(19) United States
(12) Patent Application Publication
(10) Pub. No.: US 2026/0081561 A1
(43) Pub. Date: Mar. 19, 2026

(54) MILLIMETER WAVE (MMW) RADIO FREQUENCY (RF) FRONT END

(71) Applicant: QUALCOMM INCORPORATED, SAN DIEGO, CA (US)

(72) Inventors: Alaaeldien Mohamed Abdelrazek MEDRA, San Diego, CA (US); Ran SHU, San Diego, CA (US); Yunfei FENG, San Diego, CA (US); Ojas CHOKSI, San Diego, CA (US)

(21) Appl. No.: 18/887,249

(22) Filed: Sep. 17, 2024

(51) Int. Cl. H03F 1/02; H03F 3/24; H03G 3/30; H04B 1/00; H04B 1/10

(52) U.S. Cl. CPC H03F 1/0205; H03F 3/245; H03G 3/3042; H04B 1/0057; H04B 1/10; H03F 2200/294; H03F 2200/451

(57) ABSTRACT

A radio frequency (RF) front end for a communication system includes a phase shifter having an in phase variable gain amplifier (I VGA) and a quadrature VGA (Q VGA) configured to receive radio frequency (RF) signals, the I VGA and the Q VGA configured to provide a selectable output to primary sides of first and second electromagnetic (EM) elements, respectively, the I VGA and the Q VGA configured to selectively provide DC current to a low noise amplifier (LNA).

### FIELD

The present disclosure relates generally to electronics, and more specifically to a radio frequency (RF) front end in a transceiver.

### BACKGROUND

Wireless communication devices and technologies are becoming ever more prevalent, as are communication devices that operate at millimeter-wave (mmW) and sub-terahertz (subTHz) frequencies. Wireless communication devices generally transmit and/or receive communication signals. In a radio frequency (RF) transceiver, a communication signal is typically amplified and transmitted by a transmit section and a received communication signal is amplified and processed by a receive section. A transceiver for communication in 5G and 6G applications may communicate using millimeter wave (mmW) frequency signals and/or sub-THz frequencies and may use what is referred to as a zero intermediate frequency (ZIF) architecture or a low-IF architecture.

Transceivers used in 5G communication systems may use what is referred to as beamforming to increase system capacity. Beamforming generally uses transmit and receive elements where a phase shifter alters the phase of the signal. Typically, many such elements and phase shifters are implemented in such a system. One of the challenges when implementing multiple transmit and receive elements is reducing power consumption while providing linear signal amplification.

Therefore, it would be desirable to minimize power consumption in a beamforming system in an RF front end that uses multiple transmit and receive elements.

### SUMMARY

Various implementations of systems, methods and devices within the scope of the appended claims each have several aspects, no single one of which is solely responsible for the desirable attributes described herein. Without limiting the scope of the appended claims, some prominent features are described herein.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

One aspect of the disclosure provides a radio frequency (RF) front end for a communication system including a phase shifter having an in phase variable gain amplifier (I VGA) and a quadrature VGA (Q VGA) configured to receive radio frequency (RF) signals, the I VGA and the Q VGA configured to provide a selectable output to primary sides of first and second electromagnetic (EM) elements, respectively, the I VGA and the Q VGA configured to selectively provide DC current to a low noise amplifier (LNA).

Another aspect of the disclosure provides a method for providing DC current to a low noise amplifier (LNA) in a radio frequency (RF) front end including providing radio frequency (RF) receive signals to an in phase variable gain amplifier (I VGA) and to a quadrature variable gain amplifier (Q VGA), selectively providing current from the I VGA and from the Q VGA to a low noise amplifier (LNA), and combining an output of the I VGA and the Q VGA to provide a combined output at a desired phase.

Another aspect of the disclosure provides a receive circuit including a low noise amplifier (LNA) circuit, an in phase variable gain amplifier (I VGA) and a quadrature VGA (Q VGA), each of the I VGA and the Q VGA having a gain transistor with a control terminal connected to an output of the LNA circuit, each gain transistor having a first terminal connected to a supply node of the LNA circuit and a second terminal connected to respective outputs of the I VGA and the Q VGA, and a hybrid quadrature generator (HQG) connected to the I VGA and the Q VGA.

Another aspect of the disclosure provides a device for providing DC current to a low noise amplifier (LNA) in a radio frequency (RF) front end including means for providing radio frequency (RF) receive signals to an in phase variable gain amplifier (I VGA) and to a quadrature variable gain amplifier (Q VGA), means for selectively providing current from the I VGA and from the Q VGA to a low noise amplifier (LNA), and means for combining an output of the I VGA and the Q VGA to provide a combined output at a desired phase.

### BRIEF DESCRIPTION OF THE DRAWINGS

In the figures, like reference numerals refer to like parts throughout the various views unless otherwise indicated. For reference numerals with letter character designations such as “102a” or “102b”, the letter character designations may differentiate two like parts or elements present in the same figure. Letter character designations for reference numerals may be omitted when it is intended that a reference numeral encompass all parts having the same reference numeral in all figures.

FIG. 1 is a diagram showing a wireless device communicating with a wireless communication system.

FIG. 2A is a block diagram showing a wireless device in which exemplary techniques of the present disclosure may be implemented.

FIG. 2B is a block diagram showing a wireless device in which exemplary techniques of the present disclosure may be implemented.

FIG. 2C is a block diagram showing a wireless device in which exemplary techniques of the present disclosure may be implemented.

FIG. 3 is a block diagram of two transmit (TX) and receive (RX) elements in a phased array system.

FIG. 4 is a block diagram of a circuit showing a detailed view of the phase shifter and HQG of FIG. 3.

FIG. 5 is a diagram showing a detailed view of a portion of a radio frequency (RF) front end in accordance with an exemplary embodiment.

FIG. 6 is a diagram showing a detailed view of the portion of the radio frequency (RF) front end of FIG. 5 in accordance with an exemplary embodiment.

FIG. 7 is a diagram showing a detailed view of the portion of the radio frequency (RF) front end of FIG. 5 in accordance with an exemplary embodiment.

FIG. 8 is a diagram showing a detailed view of the portion of the radio frequency (RF) front end of FIG. 5 in accordance with an exemplary embodiment.

FIG. 9 is a diagram showing a detailed view of the portion of the radio frequency (RF) front end of FIG. 5 in accordance with an exemplary embodiment.

FIG. 10 is a flow chart describing an example of the operation of a method for providing current to a low noise amplifier.

FIG. 11 is a functional block diagram of an apparatus for providing current to a low noise amplifier.

### DETAILED DESCRIPTION

The word “exemplary” is used herein to mean “serving as an example, instance, or illustration.” Any aspect described herein as “exemplary” is not necessarily to be construed as preferred or advantageous over other aspects.

In accordance with an exemplary embodiment, a millimeter wave (mmW) radio frequency (RF) front end may be implemented with a current reuse architecture that provides current from one or more variable gain amplifiers (also referred to as vector modulator amplifiers) to a low noise amplifier to minimize power consumption.

In accordance with an exemplary embodiment, a mmW RF front end may be implemented where the DC current of the in-phase (I) and quadrature (Q) branches of a vector modulator amplifier (VMA) of a phase shifter is combined and reused in the low noise amplifier (LNA) in certain operating circumstances.

In accordance with an exemplary embodiment, a mmW RF front end architecture reduces current consumption and also provides a good AC ground for both the VMA and LNA.

In accordance with an exemplary embodiment, a mmW RF front end architecture can be implemented that enhances voltage headroom and linearity of the VMA and LNA without sacrificing the power savings.

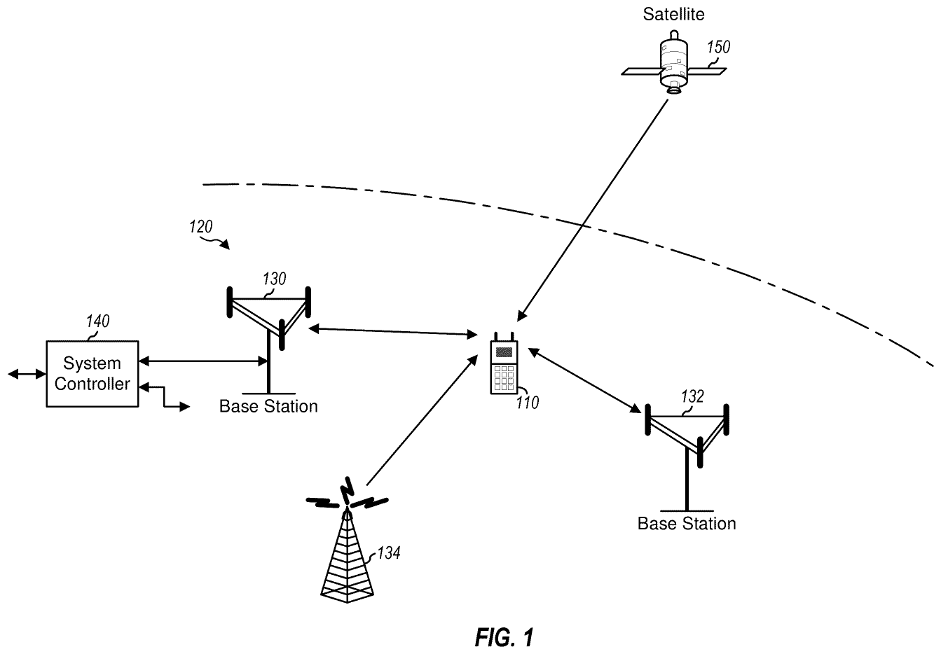

FIG. 1 is a diagram showing a wireless device 110 communicating with a wireless communication system 120. The wireless communication system 120 may be a Long Term Evolution (LTE) system, a Code Division Multiple Access (CDMA) system, a Global System for Mobile Communications (GSM) system, a wireless local area network (WLAN) system, a 5G NR (new radio) system, or some other wireless system. A CDMA system may implement Wideband CDMA (WCDMA), CDMA 1X, Evolution-Data Optimized (EVDO), Time Division Synchronous CDMA (TD-SCDMA), or some other version of CDMA. For simplicity, FIG. 1 shows wireless communication system 120 including two base stations 130 and 132 and one system controller 140. In general, a wireless communication system may include any number of base stations and any set of network entities.

The wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a tablet, a cordless phone, a medical device, an automobile, a device configured to connect to one or more other devices (for example through the internet of things), a wireless local loop (WLL) station, a Bluetooth device, etc. Wireless device 110 may communicate with wireless communication system 120. Wireless device 110 may also receive signals from broadcast stations (e.g., a broadcast station 134) and/or may communicate with satellites (e.g., a satellite 150 in one or more global navigation satellite systems (GNSS)), or a satellite that can receive signals from the wireless device 110, etc.). Wireless device 110 may support one or more radio technologies for wireless communication such as LTE, WCDMA, CDMA 1X, EVDO, TD-SCDMA, GSM, 802.11, 802.15, 5G, Sub6 5G, 6G, UWB, etc.

Wireless device 110 may support carrier aggregation, for example as described in one or more LTE or 5G standards. In some embodiments, a single stream of data is transmitted over multiple carriers using carrier aggregation, for example as opposed to separate carriers being used for respective data streams. Wireless device 110 may be able to operate in a variety of communication bands including, for example, those communication bands used by LTE, WiFi, 5G or other communication bands, over a wide range of frequencies. Wireless device 110 may also be capable of communicating directly with other wireless devices without communicating through a network.

In general, carrier aggregation (CA) may be categorized into two types-intra-band CA and inter-band CA. Intra-band CA refers to operation on multiple carriers within the same band. Inter-band CA refers to operation on multiple carriers in different bands.

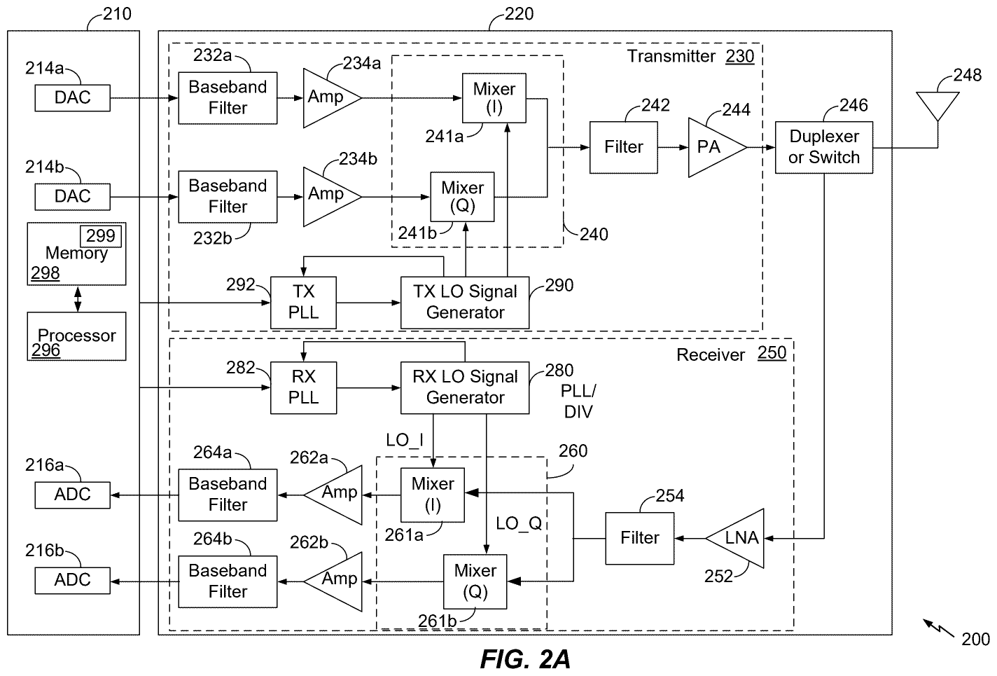

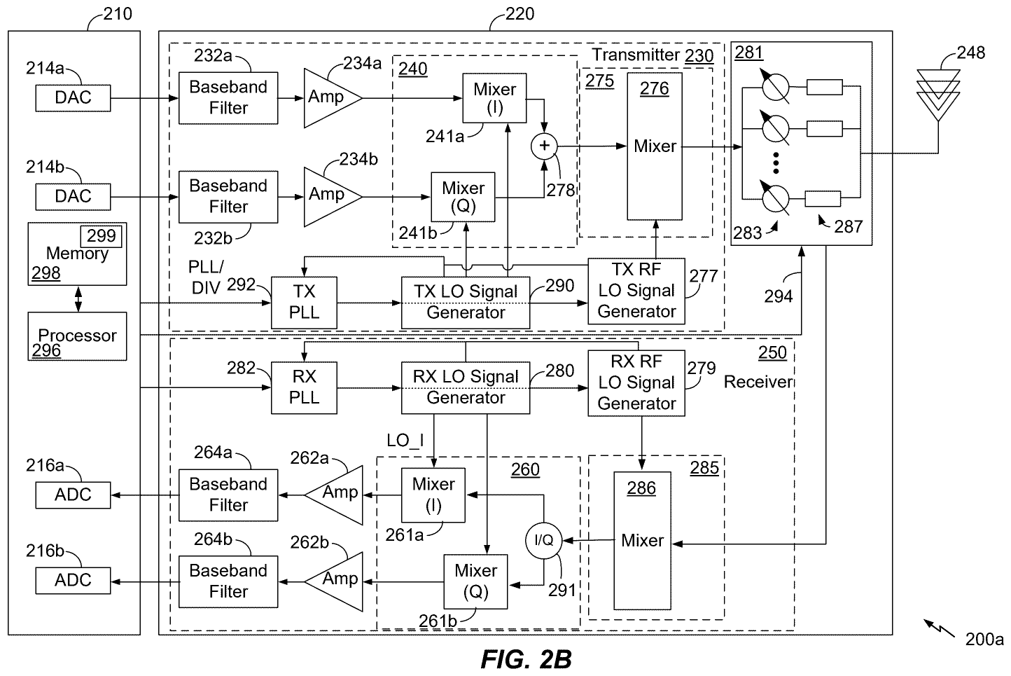

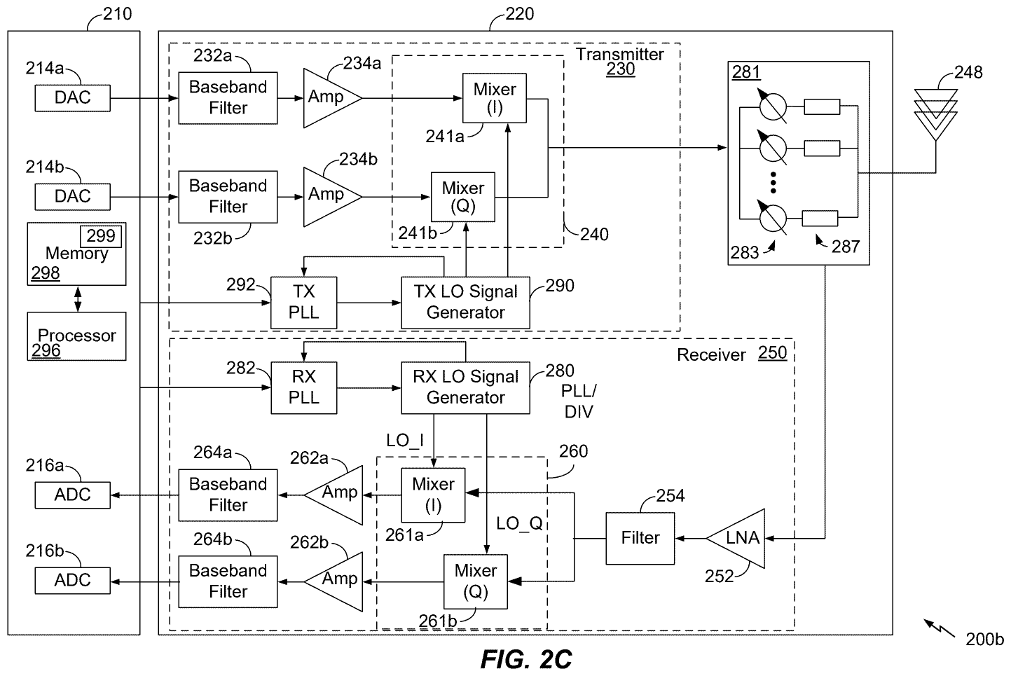

FIG. 2A is a block diagram showing a wireless device 200 in which exemplary techniques of the present disclosure may be implemented. The wireless device 200 may, for example, be an embodiment of the wireless device 110 illustrated in FIG. 1.

FIG. 2A shows an example of a transceiver 220 having a transmitter 230 and a receiver 250. In general, the conditioning of the signals in the transmitter 230 and the receiver 250 may be performed by one or more stages of amplifier, filter, upconverter, downconverter, etc. These circuit blocks may be arranged differently from the configuration shown in FIG. 2A. Furthermore, other circuit blocks not shown in FIG. 2A may also be used to condition the signals in the transmitter 230 and receiver 250. Unless otherwise noted, any signal in FIG. 2A, or any other figure in the drawings, may be either single-ended or differential. Some circuit blocks in FIG. 2A may also be omitted.

In the example shown in FIG. 2A, wireless device 200 generally comprises the transceiver 220 and a data processor 210. The data processor 210 may include a processor 296 operatively coupled to a memory 298. The memory 298 may be configured to store data and program codes shown generally using reference numeral 299, and may generally comprise analog and/or digital processing components. The processor 296 and the memory 298 may cooperate to control, configure, program, or otherwise fully or partially control some or all of the operation of the embodiments of the phase shifter and low noise amplifier (LNA) described herein.

The transceiver 220 includes a transmitter 230 and a receiver 250 that support bi-directional communication. In general, wireless device 200 may include any number of transmitters and/or receivers for any number of communication systems and frequency bands. All or a portion of the transceiver 220 may be implemented on one or more analog integrated circuits (ICs), RF ICs (RFICs), mixed-signal ICs, etc.

A transmitter or a receiver may be implemented with a super-heterodyne architecture or a direct-conversion architecture. In the super-heterodyne architecture, a signal is frequency-converted between radio frequency (RF) and baseband in multiple stages, e.g., from RF to an intermediate frequency (IF) in one stage, and then from IF to baseband in another stage for a receiver. In the direct-conversion architecture, a signal is frequency converted between RF and baseband in one stage. The super-heterodyne and direct-conversion architectures may use different circuit blocks and/or have different requirements. In the example shown in FIG. 2A, transmitter 230 and receiver 250 are implemented with the direct-conversion architecture.

In the transmit path, the data processor 210 processes data to be transmitted and provides in-phase (I) and quadrature (Q) analog output signals to the transmitter 230. In an exemplary embodiment, the data processor 210 includes digital-to-analog-converters (DAC's) 214a and 214b for converting digital signals generated by the data processor 210 into the I and Q analog output signals, e.g., I and Q output currents, for further processing. In other embodiments, the DACs 214a and 214b are included in the transceiver 220 and the data processor 210 provides data (e.g., for I and Q) to the transceiver 220 digitally.

Within the transmitter 230, baseband (e.g., lowpass) filters 232a and 232b filter the I and Q analog transmit signals, respectively, to remove undesired images caused by the prior digital-to-analog conversion. Amplifiers (Amp) 234a and 234b amplify the signals from baseband filters 232a and 232b, respectively, and provide I and Q baseband signals. An upconverter 240 having upconversion mixers 241a and 241b upconverts the I and Q baseband signals with I and Q transmit (TX) local oscillator (LO) signals from a TX LO signal generator 290 and provides an upconverted signal. A filter 242 filters the upconverted signal to remove undesired images caused by the frequency upconversion as well as noise in a receive frequency band. A power amplifier (PA) 244 amplifies the signal from filter 242 to obtain the desired output power level and provides a transmit RF signal. The transmit RF signal may be routed through a duplexer or switch 246 and transmitted via an antenna 248. While examples discussed herein utilize I and Q signals, those of skill in the art will understand that components of the transceiver may be configured to utilize polar modulation.

In the receive path, antenna 248 receives communication signals and provides a received RF signal, which may be routed through duplexer or switch 246 and provided to a low noise amplifier (LNA) 252. The duplexer 246 is designed to operate with a specific RX-to-TX duplexer frequency separation, such that RX signals are isolated from TX signals. The received RF signal is amplified by LNA 252 and filtered by a filter 254 to obtain a desired RF input signal.

Downconversion mixers 261a and 261b in a downconverter 260 mix the output of filter 254 with I and Q receive (RX) LO signals (i.e., LO_I and LO_Q) from an RX LO signal generator 280 to generate I and Q baseband signals. The I and Q baseband signals are amplified by amplifiers 262a and 262b and further filtered by baseband (e.g., lowpass) filters 264a and 264b to obtain I and Q analog input signals, which are provided to data processor 210. In the exemplary embodiment shown, the data processor 210 includes analog-to-digital-converters (ADC's) 216a and 216b for converting the analog input signals into digital signals to be further processed by the data processor 210. In some embodiments, the ADCs 216a and 216b are included in the transceiver 220 and provide data to the data processor 210 digitally.

In FIG. 2A, TX LO signal generator 290 generates the I and Q TX LO signals used for frequency upconversion, while RX LO signal generator 280 generates the I and Q RX LO signals used for frequency downconversion. Each LO signal is a periodic signal with a particular fundamental frequency. A phase locked loop (PLL) 292 receives timing information from data processor 210 and generates a control signal used to adjust the frequency and/or phase of the TX LO signals from LO signal generator 290. Similarly, a PLL 282 receives timing information from data processor 210 and generates a control signal used to adjust the frequency and/or phase of the RX LO signals from LO signal generator 280.

Wireless device 200 may support CA and may (i) receive multiple downlink signals transmitted by one or more cells on multiple downlink carriers at different frequencies and/or (ii) transmit multiple uplink signals to one or more cells on multiple uplink carriers. Those of skill in the art will understand, however, that aspects described herein may be implemented in systems, devices, and/or architectures that do not support carrier aggregation.

Certain components of the transceiver 220 are functionally illustrated in FIG. 2A, and the configuration illustrated therein may or may not be representative of a physical device configuration in certain implementations. For example, as described above, transceiver 220 may be implemented in various integrated circuits (ICs), RF ICs (RFICs), mixed-signal ICs, etc. In some embodiments, the transceiver 220 is implemented on a substrate or board such as a printed circuit board (PCB) having various modules, chips, and/or components. For example, the power amplifier 244, the filter 242, and the duplexer 246 may be implemented in separate modules or as discrete components, while the remaining components illustrated in the transceiver 220 may be implemented in a single transceiver chip.

The power amplifier 244 may comprise one or more stages comprising, for example, driver stages, power amplifier stages, or other components, that can be configured to amplify a communication signal on one or more frequencies, in one or more frequency bands, and at one or more power levels. Depending on various factors, the power amplifier 244 can be configured to operate using one or more driver stages, one or more power amplifier stages, one or more impedance matching networks, and can be configured to provide good linearity, efficiency, or a combination of good linearity and efficiency.

In an exemplary embodiment in a super-heterodyne architecture, the PA 244 and LNA 252 (and filter 242 and filter 254 in some examples) may be implemented separately from other components in the transmitter 230 and receiver 250, for example on a millimeter wave integrated circuit. An example super-heterodyne architecture is illustrated in FIG. 2B.

FIG. 2B is a block diagram showing a wireless device in which exemplary techniques of the present disclosure may be implemented. Certain components, for example which may be indicated by identical reference numerals, of the wireless device 200a in FIG. 2B may be configured similarly to those in the wireless device 200 shown in FIG. 2A and the description of identically numbered items in FIG. 2B will not be repeated.

The wireless device 200a is an example of a heterodyne (or superheterodyne) architecture in which the upconverter 240 and the downconverter 260 are configured to process a communication signal between baseband and an intermediate frequency (IF). The IF signal may be a low IF (LIF) signal, or a zero (or near zero) IF (ZIF) signal. For example, the upconverter 240 may include a summing function 278 and may be configured to provide an IF signal to an upconverter 275. In an exemplary embodiment, the upconverter 275 may comprise upconversion mixer 276. The summing function 278 combines the I and the Q outputs of the upconverter 240 and provides a non-quadrature signal to the mixer 276. The non-quadrature signal may be single ended or differential. The mixer 276 is configured to receive the IF signal from the upconverter 240 and TX RF LO signals from a TX RF LO signal generator 277, and provide an upconverted RF signal to phase shift circuitry 281. While PLL 292 is illustrated in FIG. 2B as being shared by the signal generators 290, 277, a respective PLL for each signal generator may be implemented.

In an exemplary embodiment, components in the phase shift circuitry 281 may comprise one or more adjustable or variable phased array elements, and may receive one or more control signals from the data processor 210 over connection 294 and operate the adjustable or variable phased array elements based on the received control signals.

In an exemplary embodiment, the phase shift circuitry 281 comprises phase shifters 283 and phased array elements 287. Although three phase shifters 283 and three phased array elements 287 are shown for ease of illustration, the phase shift circuitry 281 may comprise more or fewer phase shifters 283 and phased array elements 287. For example, one or two arrays of four or five antennas and corresponding phase shifters/phased array elements may be implemented.

Each phase shifter 283 may be configured to receive the RF transmit signal from the upconverter 275, alter the phase by an amount, and provide the RF signal to a respective phased array element 287. Each phased array element 287 may comprise transmit and receive circuitry including one or more filters, amplifiers, driver amplifiers, low noise amplifiers, and/or power amplifiers. In some embodiments, the phase shifters 283 may be incorporated within respective phased array elements 287.

The output of the phase shift circuitry 281 is provided to an antenna array 248. In an exemplary embodiment, the antenna array 248 comprises a number of antennas that typically correspond to the number of phase shifters 283 and phased array elements 287, for example such that each antenna element is coupled to a respective phased array element 287. In an exemplary embodiment, the phase shift circuitry 281 and the antenna array 248 may be referred to as a phased array.

In a receive direction, an output of the phase shift circuitry 281 is provided to a downconverter 285. In an exemplary embodiment, the downconverter 285 may comprise a downconversion mixer 286. In an exemplary embodiment, the mixer 286 downconverts the receive RF signal provided by the phase shift circuitry 281 to an IF signal according to RX RF LO signals provided by an RX RF LO signal generator 279. The downconverter 260 includes an I/Q generation function 291. The I/Q generation function 291 receives the IF signal from the mixer 286 and generates I and Q signals for the downconverter 260, which downconverts the IF signals to baseband, as described above. While PLL 282 is illustrated in FIG. 2B as being shared by the signal generators 280, 279, a respective PLL for each signal generator may be implemented.

In some embodiments, the upconverter 275, downconverter 285, and the phase shift circuitry 281 are implemented on a common IC. In some embodiments, the summing function 278 and the I/Q generation function 291 are implemented separate from the mixers 276 and 286 such that the mixers 276, 286 and the phase shift circuitry 281 are implemented on the common IC, but the summing function 278 and I/Q generation function 291 are not (e.g., the summing function 278 and I/Q generation function 291 are implemented in another IC coupled to the IC having the mixers 276, 286). In some embodiments, the LO signal generators 277, 279 are included in the common IC. In some embodiments in which phase shift circuitry is implemented on a common IC with 276, 286, 277, 278, 279, and/or 291, the common IC and the antenna array 248 are included in a module, which may be coupled to other components of the transceiver 220 via a connector. In some embodiments, the phase shift circuitry 281, for example, a chip on which the phase shift circuitry 281 is implemented, is coupled to the antenna array 248 by an interconnect or both are mounted to a substrate. For example, components of the antenna array 248 may be implemented on a substrate and coupled to an integrated circuit implementing the phase shift circuitry 281 via a flexible printed circuit or the integrated circuit may be mounted to an opposite side of the substrate.

In some embodiments, both the architecture illustrated in FIG. 2A and the architecture illustrated in FIG. 2B are implemented in the same device. For example, a wireless device 110 or 200 may be configured to communicate with signals having a frequency below about 20 GHz using the architecture illustrated in FIG. 2A and to communicate with signals having a frequency above about 20 GHz using the architecture illustrated in FIG. 2B. In devices in which both architectures are implemented, one or more components of FIGS. 2A and 2B that are identically numbered may be shared between the two architectures. For example, both signals that have been downconverted directly to baseband from RF and signals that have been downconverted from RF to baseband via an IF stage may be filtered by the same baseband filter 264. In other embodiments, a first version of the filter 264 is included in the portion of the device which implements the architecture of FIG. 2A and a second version of the filter 264 is included in the portion of the device which implements the architecture of FIG. 2B. While certain example frequencies are described herein, other implementations are possible. For example, signals having a frequency above about 20 GHz (e.g., having a mmW frequency) may be transmitted and/or received using a direct conversion architecture. In such embodiments, for example, a phased array may be implemented in the direct conversion architecture.

FIG. 2C is a block diagram showing a wireless device in which exemplary techniques of the present disclosure may be implemented. Certain components, for example which may be indicated by identical reference numerals, of the wireless device 200b in FIG. 2C may be configured similarly to those in the wireless device 200 shown in FIG. 2A and/or the wireless device 200a shown in FIG. 2B and the description of identically numbered items in FIG. 2C will not be repeated.

The wireless device 200b in FIG. 2C incorporates the phase shift circuitry 281 (of FIG. 2B) in a direct conversion architecture, where mmW transmission signals are upconverted and downconverted between baseband and RF without the use of intermediate frequency (IF) signal conversion. For example, the LO signals in the architecture of FIG. 2C may comprise signals at frequencies of tens of GHz.

In some embodiments, the upconverter 240, downconverter 260, and the phase shift circuitry 281 are implemented on a common IC. In some embodiments, the LO signal generators 280, 290 are included in the common IC. In some embodiments, the common IC and the antenna array 248 are included in a module, which may be coupled to other components of the transceiver 220 via a connector. In some embodiments, the phase shift circuitry 281, for example, a chip on which the phase shift circuitry 281 is implemented, is coupled to the antenna array 248 by an interconnect or both are mounted to a substrate. For example, components of the antenna array 248 may be implemented on a substrate and coupled to an integrated circuit implementing the phase shift circuitry 281 via a flexible printed circuit or the integrated circuit may be mounted to an opposite side of the substrate.

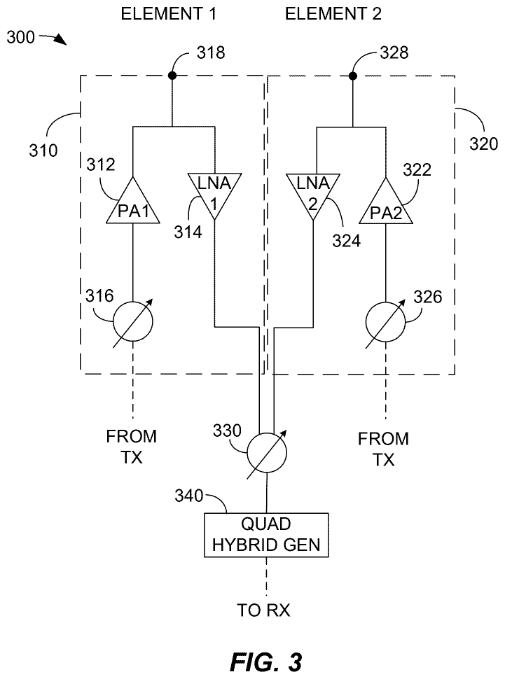

FIG. 3 is a block diagram 300 of two transmit (TX) and receive (RX) elements in a phased array system, for example as may be included in the phase shift circuitry 281. A first element 310 may comprise TX circuitry including a power amplifier (PA) 312 and RX circuitry including a low noise amplifier (LNA) 314. A second element 320 may comprise TX circuitry including a power amplifier (PA) 322 and RX circuitry including a low noise amplifier (LNA) 324. The first element 310 and the second element 320 may be part of a phased array system having many tens or hundreds of elements, or having fewer elements. A node 318 and a node 328 may be connected to an antenna or an antenna element in an antenna array. The first element 310 may also comprise a TX phase shifter 316 and the second element 320 may also comprise a TX phase shifter 326.

A receive phase shifter 330 may be connected to the LNA 314 and to the LNA 324. In accordance with an exemplary embodiment of the disclosure, a single RX phase shifter 330 represents a portion of a phase shifter circuit that includes, for example, a vector modulator circuit and an electromagnetic coupling circuit. In an exemplary embodiment, the electromagnetic coupling circuit may be shared between the LNA 314 and the LNA 324, as will be described below. An output of the phase shifter 330 is provided to a hybrid quadrature generator (HQG) 340. In an exemplary embodiment, the HQG 340 may also be shared between the LNA 314 and the LNA 324.

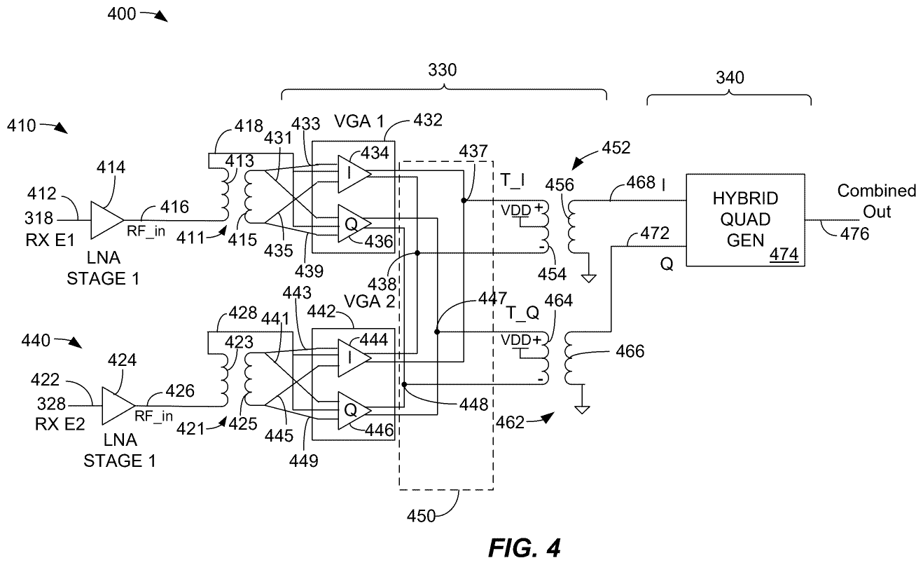

FIG. 4 is a block diagram of a circuit 400 showing a detailed view of the phase shifter 330 and HQG 340 of FIG. 3. In an exemplary embodiment, the circuit 400 may include a first signal path 410 and a second signal path 440. The first signal path 410 may comprise a low noise amplifier 414, a magnetic circuit 411 and a variable gain amplifier (VGA) 432. The VGA 432 may also be referred to as a vector modulator amplifier (VMA). In an exemplary embodiment, the LNA 414 may comprise a first stage LNA, and may be an example of the LNA 314 of FIG. 3. In an exemplary embodiment, the magnetic circuit 411 may comprise a primary side 413 and a secondary side 415. The primary side 413 may be connected to a connection 418 that represents an AC ground point for the VGA 432.

The VGA 432 may comprise a VGA 434 configured to amplify signals for an in phase (I) component (I VGA) and a VGA 436 configured to amplify signals for a quadrature (Q) component (Q VGA).

In an exemplary embodiment, the VGA 432 may be a differential device and may include two (2) differential input I/Q variable gain amplifiers (VGAs) 434 and 436. In other embodiments, the VGA 432 may be a single-ended device and may include two (2) single-ended input I/Q variable gain amplifiers (VGAs) 434 and 436. In some embodiments, the VGA 432 may be configured to receive a differential input signal and provide a single-ended output.

In an exemplary embodiment, one terminal of the secondary side 415 may be connected to the VGA 434 over connection 433 and may be connected to the VGA 436 over connection 431. In an exemplary embodiment, another terminal of the secondary side 415 may be connected to the VGA 434 over connection 435 and may be connected to the VGA 436 over connection 439.

In an exemplary embodiment, the connection 418 connects to the VGA 434 and the VGA 436. The connection 418 creates a path over which DC current from the VGA 434 and from the VGA 436 can be provided to the LNA 414 under certain operating conditions.

The second signal path 440 may comprise a low noise amplifier 424, a magnetic circuit 421 and a variable gain amplifier (VGA) 442. The VGA 442 may also be referred to as a vector modulator amplifier (VMA). In an exemplary embodiment, the LNA 424 may comprise a first stage LNA, and may be an example of the LNA 324 of FIG. 3. In an exemplary embodiment, the magnetic circuit 421 may comprise a primary side 423 and a secondary side 425. The primary side 423 may be connected to a connection 428 that represents an AC ground point for the VGA 442.

The VGA 442 may comprise a VGA 444 configured to amplify signals for an in phase (I) component (I VGA) and a VGA 446 configured to amplify signals for a quadrature (Q) component (Q VGA).

In an exemplary embodiment, the VGA 442 may be a differential device and may include two (2) differential input I/Q variable gain amplifiers (VGAs) 444 and 446. In other embodiments, the VGA 442 may be a single-ended device and may include two (2) single-ended input I/Q variable gain amplifiers (VGAs) 444 and 446. In some embodiments, the VGA 442 may be configured to receive a differential input signal and provide a single-ended output.

In an exemplary embodiment, one terminal of the secondary side 425 may be connected to the VGA 444 over connection 443 and may be connected to the VGA 446 over connection 441. In an exemplary embodiment, another terminal of the secondary side 425 may be connected to the VGA 444 over connection 445 and may be connected to the VGA 446 over connection 449.

In an exemplary embodiment, the connection 428 connects to the VGA 444 and the VGA 446. The connection 428 creates a path over which DC current from the VGA 444 and from the VGA 446 can be provided to the LNA 424 under certain operating conditions.

An output of the VGA 434 is provided to the node 437 and to the node 438. An output of the VGA 436 is provided to the node 447 and to the node 448. An output of the VGA 444 is provided to the node 437 and to the node 438. An output of the VGA 446 is provided to the node 447 and to the node 448.

The node 437 is connected to one terminal of a first side 454 of a transformer 452 and the node 438 is connected to another terminal of the first side 454 of the transformer 452. The node 447 is connected to one terminal of a first side 464 of a transformer 462 and the node 448 is connected to another terminal of the first side 464 of the transformer 462. A first terminal of the second side 456 of the transformer 452 is connected to the connection 468 and a first terminal of the second side 466 of the transformer 462 is connected to the connection 472.

As used herein, the “term pseudo-differential output transformation” refers to the VGAs 434 and 436 being single-ended and selectively providing separate single-ended outputs to the nodes 437, 438, 447 and 448, as is further explained below. The VGA 444 and the VGA 446 are similarly configured. In an exemplary embodiment, a “psuedo-differential output transformation” also refers to the way signals at the node 437 and the node 438 appear in phase, but would appear out of phase by 180 degrees at the connection 468. Similarly, signals at the node 447 and the node 448 appear in phase, but would appear out of phase by 180 degrees at the connection 472. In an exemplary embodiment, the VGA 434 provides two separate single-ended outputs, where one single-ended output is selectively provided to node 437 and the other single-ended output is selectively provided to node 438. The VGA 436 provides two separate single-ended outputs, where one single-ended output is selectively provided to node 447 and the other single-ended output is selectively provided to node 448. Similarly, the VGA 444 provides two separate single-ended outputs, where one single-ended output is selectively provided to node 437 and the other single-ended output is selectively provided to node 438; and the VGA 446 provides two separate single-ended outputs, where one single-ended output is selectively provided to node 447 and the other single-ended output is selectively provided to node 448.

For example, the “same” signal from the VGA 434 would be provided to node 437 or to node 438 depending on the desired polarity (or sign, 0/180) at the connection 468. A signal provided from the VGA 434 to the node 437 would undergo some intrinsic amount of phase shift before appearing at the connection 468 due to the components it passes through (e.g., an intrinsic phase shift of “theta”). If that “same” signal was provided from the VGA 434 to the connection 468 via the node 438 instead, then that intrinsic phase shift would be theta+180 degrees.

The signal on connection 468 and the signal on connection 472 may be provided to the HQG 474 simultaneously. In an exemplary embodiment, the operation of the HQG 474 takes the signals on connections 468 and 472 as inputs and produces the output on connection 476 according to the operation I+j*Q, where j represents a 90 degree phase shift, I is the signal on connection 468 and Q is the signal on connection 472. The signal that appears at connection 476 due to the signal on connection 472 (Q) is 90 degrees shifted from the signal that appears at the output on connection 476 due to the signal on connection 468 (I).

In an exemplary embodiment, placing the VGAs 432 and 442 ahead of the HQG 474 in the signal paths 410 and 440, allows the number of stages in the LNA to be reduced, thereby saving area while conserving the receiver noise figure. In an exemplary embodiment, the VGAs 432 and 442 perform amplification and vector modulation to effectively provide phase shift to the signals on connections 416 and 426 from the two separate signal paths 410 and 440.

In an exemplary embodiment, the outputs of the VGA 432 and the outputs of the VGA 442 are provided to a connection network 450. The connection network 450 may be any network capable of providing the separate I outputs from the VGAs 434 and 444, and the separate Q outputs from the VGAs 436 and 446 to the positive and negative terminals of the primary sides of the transformers 452 and 462. For example, the separate I outputs of the VGA 434 may be selectively provided to a node 437 and to a node 438. Similarly, the separate I outputs of the VGA 444 may be selectively provided to the node 437 and to the node 438. Similarly, the separate Q outputs of the VGA 436 may be selectively provided to a node 447 and to a node 488. Similarly, the separate Q outputs of the VGA 446 may be selectively provided to the node 447 and to the node 448. As will be described in greater detail below, the outputs of the I VGA 434 and the I VGA 444 may be selectively controlled by controlling the current flow through the I VGA 434 and the I VGA 444. Similarly, the outputs of the Q VGA 436 and the Q VGA 446 may be selectively controlled by controlling the current flow through the Q VGA 436 and the Q VGA 446.

In an exemplary embodiment, the transformer 452 may be configured to receive the in phase (I) signals and includes a primary side 454 and a secondary side 456. In an exemplary embodiment, the transformer 462 may be configured to receive the quadrature (Q) signals and includes a primary side 464 and a secondary side 466.

In an exemplary embodiment, the primary side 454 and the primary side 464 may be configured to receive “positive” or “negative” signals and the secondary side 456 and the secondary side 466 may be configured to provide single-ended signals. In an exemplary embodiment, the transformers 452 and 462 can be driven from their respective positive terminals (node 437 or node 447) or their negative terminals (node 438 or node 448) or a combination of the positive and negative terminals if receiving signals from both the VGA 432 and the VGA 442 simultaneously.

An I output of the transformer 452 may be provided to the HQG 474 over connection 468 and the Q output of the transformer 462 may be provided to the HQG 474 over connection 472. The output of the HQG 474 on connection 476 is a combined output at a desired phase between 0 and 360 degrees.

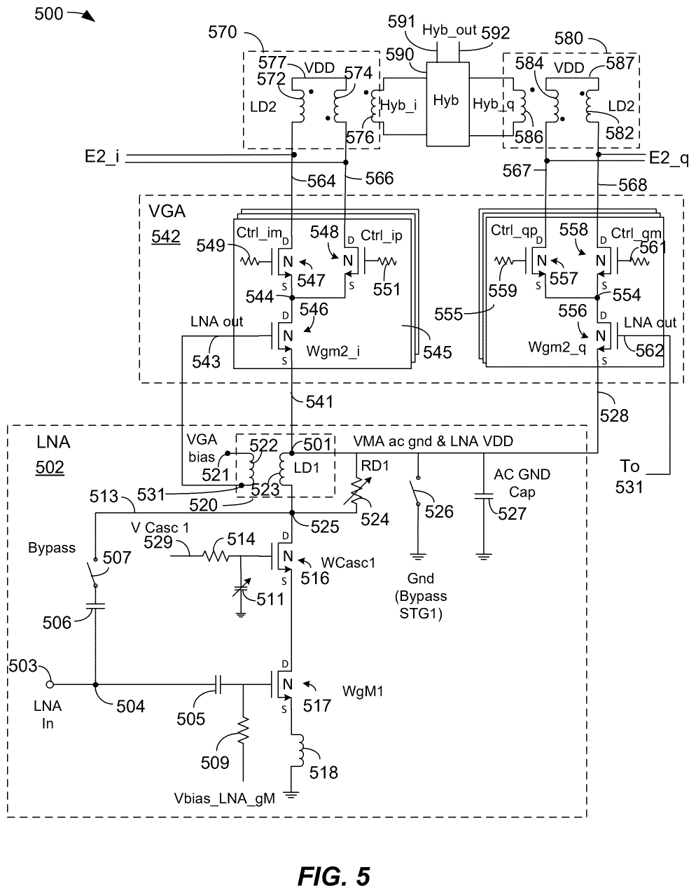

FIG. 5 is a diagram 500 showing a detailed view of a portion of a radio frequency (RF) front end in accordance with an exemplary embodiment. An RF front end 500 may comprise a low noise amplifier (LNA) 502, a variable gain amplifier (VGA) (sometimes also referred to as a vector modulator amplifier (VMA)) 542, a combining circuit 570, a combining circuit 580 and a hybrid quadrature generator (HQG) 590.

In an exemplary embodiment, the LNA 502 may include a transistor 517, a transistor 516 and a magnetic circuit 520. In an exemplary embodiment, the transistor 517 may be a gain transistor (WgM1) and the transistor 516 may be a cascode transistor (WCasc1). The source of the transistor 517 may be connected to system ground through an inductor 518 in a configuration known as source degeneration. The gate of the transistor 517 may be biased with a bias voltage, Vbias_LNA_gM, through a resistance 509 and may be connected to a node 504 through a capacitance 505. The node 504 may be connected to a node 503 from which a radio frequency (RF) input signal may be applied. The drain of the transistor 517 may be connected to the source of the transistor 516.

The drain of the transistor 516 may be connected to a node 525, which is also connected to one side 523 of the magnetic circuit 520. The side 523 may also be connected to an adjustable resistance 524, a switch 526 and a capacitance 527 at a node 501. A gate of the transistor 516 may be connected to a resistance 514 and an adjustable capacitance 511. A bias voltage, VCasc1 may be generated by a bias circuit (not shown) and is applied over connection 529 to the gate of the transistor 516 through the resistance 514.

A capacitance 506 is connected between the node 504 and a first side of a switch 507. The other side of the switch 507 is connected over connection 513 to the node 525. The magnetic circuit 520 includes the first side 523 and a second side 522. The first side 523 and the second side 522 are magnetically coupled. A first terminal of the second side 522 is connected to a VGA bias voltage at a node 521. The VGA bias voltage at node 521 is also an AC ground. The other terminal of the second side 522 is connected to the VGA 542 over a connection 543 and a connection 562 at a node 531. The connection from the node 531 to the connection 562 is omitted from the drawing for simplicity of illustration. One terminal of the first side 523 is connected to the node 525 and the other terminal of the first side 523 is connected to the node 501. The node 501 is connected to the VGA 542 over connection 541 and over connection 528. The connection 528 and the node 501 also form an AC ground for the VGA 542 and is also the supply voltage, VDD, for the LNA 502.

In an exemplary embodiment, the VGA 542 comprises an I VGA 545 and a Q VGA 555. Each of the I VGA 545 and the Q VGA 555 may comprise multiple instances, sometimes referred to as slices, but a single I VGA and a single Q VGA is shown in detail in FIG. 5 for example only.

The I VGA 545 includes a gain transistor 546 and transistors 547 and 548. In an exemplary embodiment, the transistors 547 and 548 are implemented and illustrated as switches and include respective resistances 549 and 551 connected to the gates of the transistors 547 and 548, respectively. A source of the transistor 546 is connected to the node 501 over connection 541. A drain of the transistor 546 is connected to the source of the transistor 547 and the source of the transistor 548 at a node 544. A control signal, Ctrl_im is provided to the gate of the transistor 547 through the resistor 549 and a control signal, Ctrl_ip, is provided to the gate of the transistor 548 through a resistor 551. The control signals Ctrl_im and Ctrl_ip may be provided by the data processor 210 (FIGS. 2A, 2B, 2C) or another controller.

The Q VGA 555 includes a gain transistor 556 and transistors 557 and 558. In an exemplary embodiment, the transistors 557 and 558 are implemented and illustrated as switches and include respective resistances 559 and 561 connected to the gates of the transistors 557 and 558, respectively. A source of the transistor 556 is connected to the node 501 over connection 528. A drain of the transistor 556 is connected to the source of the transistor 557 and the source of the transistor 558 at a node 554. A control signal, Ctrl_iq is provided to the gate of the transistor 557 through a resistor 559 and a control signal, Ctrl_qp, is provided to the gate of the transistor 558 through a resistor 561. The control signals Ctrl_qm and Ctrl_qp may be provided by the data processor 210 (FIGS. 2A, 2B, 2C) or another controller.

In an exemplary embodiment, an output of the I VGA 545 is provided over connections 564 and 566, and an output of the Q VGA 555 is provided over connections 567 and 568. The output of the I VGA 545 is provided either on connections 564 or 566 depending on the desired phase to be provided to the HQG 590 and represents a phase shifted version of the I signal processed by the I VGA 545 and the output of the Q VGA 555 is provided either on connections 567 or 568 depending on the desired phase to be provided to the HQG 590 and represents a phase shifted version of the Q signal processed by the Q VGA 555. The signals on connections 564 and 566 are provided to a magnetic circuit 570 and the signals on connections 567 and 568 are provided to a magnetic circuit 580.

In an exemplary embodiment, the magnetic circuit 570 is referred to as a tri-coil and may include a first side 572, a second side 574 and a third side 576. A voltage, VDD is provided to a connection 577 between the first side 572 and the second side 574. An output signal is provided from the third side 576 to the HQG 590.

In an exemplary embodiment, the magnetic circuit 580 is referred to as a tri-coil and may include a first side 582, a second side 584 and a third side 586. A voltage, VDD is provided to a connection 587 between the first side 582 and the second side 584. An output signal is provided from the third side 586 to the HQG 590. The output of the HQG 590 is provided over connections 591 and 592.

In an exemplary embodiment, connections labeled E2_i are connected to the connections 564 and 566, and connections labeled E2_q are connected to the connections 567 and 568. The connections E2_i and E2_q exist so that multiple elements (not shown) can be combined to share the magnetic circuit 570 and the magnetic circuit 580.

In an exemplary embodiment, the HQG 590 combines the output of the I VGA 545 on connections 564 and 566 and the output of the Q VGA 555 on connections 567 and 568 and provides a combined output at a desired phase on connections 591 and 592.

In an exemplary embodiment, under certain operating conditions, DC current from the I VGA 545 and the Q VGA 555 may be provided to the LNA 502 over connections 541 and 528 and combined at the node 501 in what is referred to as a current reuse architecture where the DC current from the from the I VGA 545 and the Q VGA 555 is reused by the LNA 502.

In an exemplary embodiment, the connections 541 and 528 may be considered AC ground connections for the I VGA 545 and the Q VGA 555, while the node 501, from a DC perspective, may be considered VDD for the LNA 502. In other words, the DC voltage at the source of the transistor 546 and the transistor 556 is the supply voltage of the LNA 502. In an exemplary embodiment, from an AC perspective, the capacitance 527 provides an AC ground for the LNA 502 at the node 501.

In an exemplary embodiment, the single gain stage (transistor 546 in the I VGA 545 and the single gain stage (transistor 556 in the Q VGA 555) in the VGA 542 reduces current consumption and reduces the amount of load on the LNA 502 compared to having one gain (gM) transistor for each transistor 547 and 548 in the I VGA 545 and each transistor 557 and 558 in the Q VGA 555. This architecture reduces the capacitance experienced by the LNA 502 because the LNA is loaded by only a single gain (gM) stage (transistor 546 and transistor 556), resulting in higher LNA gain.

In an exemplary embodiment, implementing the transistors 547, 548, 557 and 558 as switches (instead of cascode transistors) may improve the voltage headroom of the VGA 542.

In an exemplary embodiment, in a low gain mode, there is no DC current flowing through the LNA 502, which results in improved linearity and provides the VGA 542 additional voltage headroom.

In an exemplary embodiment, in a high gain mode, the VGA 542 and the LNA 502 can tolerate lower supply voltage and the resulting lower linearity is acceptable due to the high gain operation.

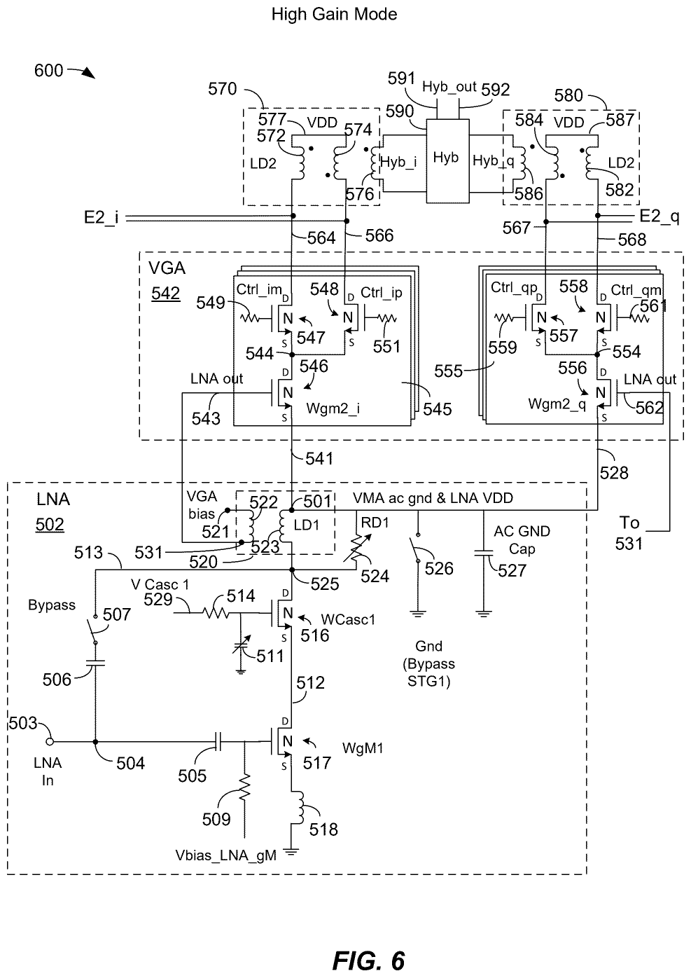

FIG. 6 is a diagram 600 showing a detailed view of the portion of the radio frequency (RF) front end of FIG. 5 in accordance with an exemplary embodiment. The diagram 600 shows the portion of the RF front end in a high-gain mode. The term “high-gain” is relative. In some embodiments, the term “high-gain” corresponds to a gain setting referred to as ranging from G0-G3. In an exemplary embodiment, the LNA gain can be affected by a number of factors. For example, to reduce the current at the LNA 502, the current provided by the VGA 542 can be reduced. In an exemplary embodiment, the current provided by the I_VGA 545 and the Q_VGA 555 can be independently controlled so that the DC current provided to the LNA 502 at the node 501 can be reduced. However, when the current through the VGA 542 is reduced, the ratio of the current through the I_VGA 545 and the current through the Q_VGA 555 should be maintained depending on the phase desired at the output of the HQG 590. In an exemplary embodiment, the resistor 524 can also be used to attenuate the output of the LNA 502. In an exemplary embodiment, the cascode transistor 516 may be configured to operate as a switch not a cascode amplifier while switching off the capacitance 511. In high-gain mode, DC current from the I VGA 545 and the Q VGA 555 is provided over connections 541 and 528 to the node 501 to supply additional DC current to the LNA 502. In high-gain mode, the VGA 542 can tolerate lower supply voltage and the resulting reduction in linearity is acceptable.

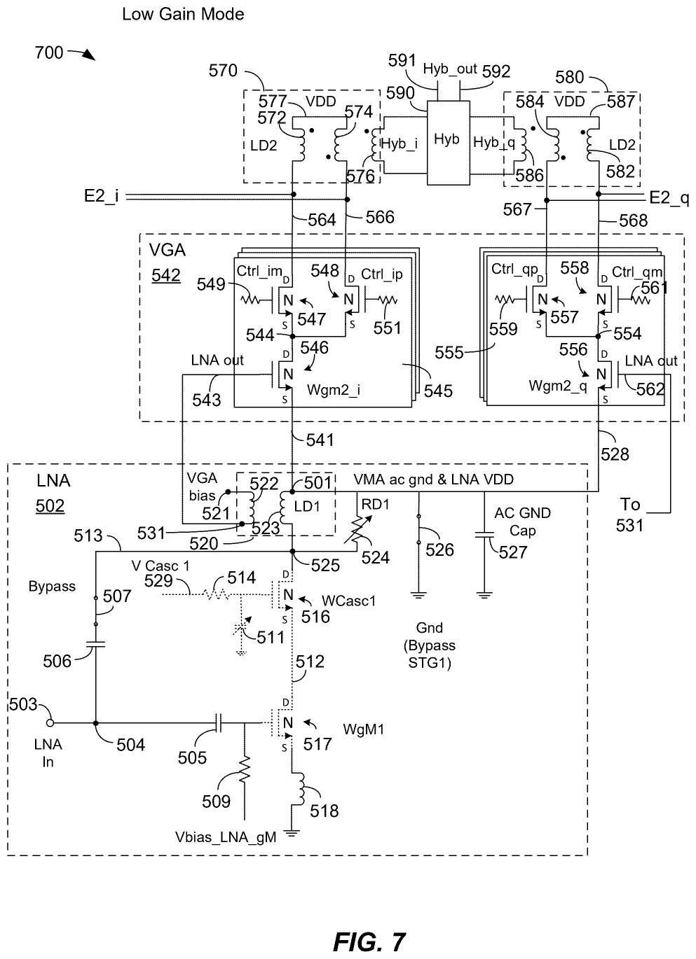

FIG. 7 is a diagram 700 showing a detailed view of the portion of the radio frequency (RF) front end of FIG. 5 in accordance with an exemplary embodiment. The diagram 700 shows the portion of the RF front end in a low-gain mode. The term “low-gain” is relative. In some embodiments, the term “low-gain” corresponds to a gain setting referred to as ranging from G4-G5. In an exemplary embodiment, the switch 507 is conductive bypassing the LNA 502 and the switch 526 is conductive, effectively providing DC ground at node 501 to provide VGA current a path to ground because the transistors 516 and 517 are turned off, thereby placing the LNA 502 in a bypass mode. In such a bypass mode, the voltage headroom of the VMA 542 is increased, thereby increasing the linearity of the VGA 542.

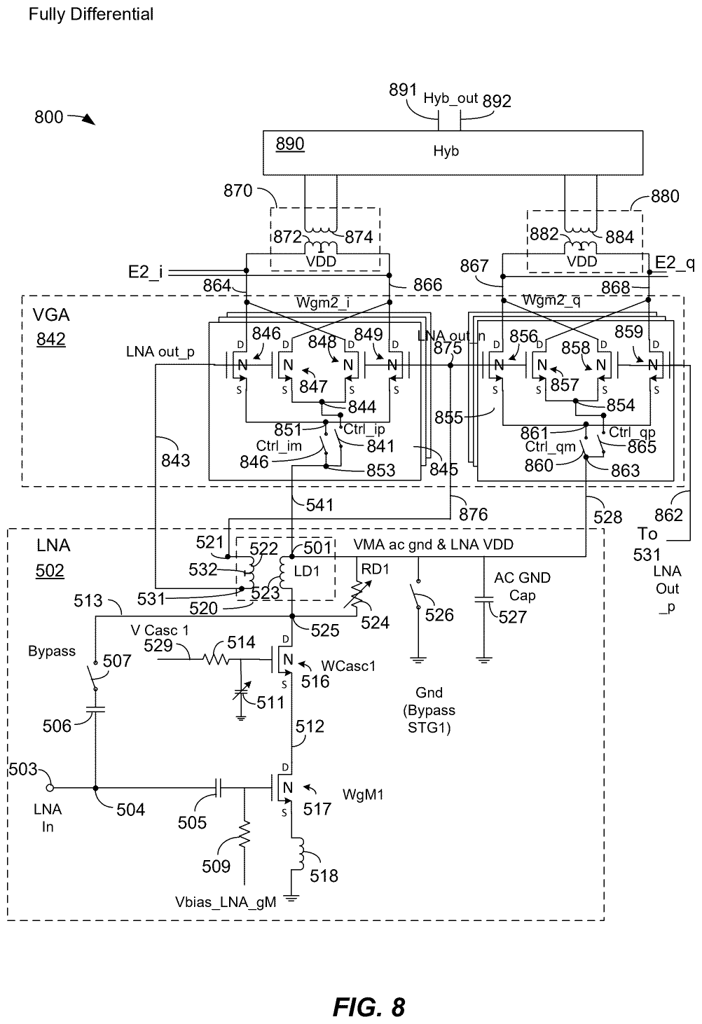

FIG. 8 is a diagram 800 showing a detailed view of the portion of the radio frequency (RF) front end of FIG. 5 in accordance with an exemplary embodiment. The diagram 800 shows the portion of the RF front end in a fully differential implementation. Elements in FIG. 8 that are identical to those in FIG. 5 will be identically numbered. In an exemplary embodiment, in a fully differential implementation, the VGA 842 includes an I VGA 845 and a Q VGA 855.

In an exemplary embodiment, the I VGA 845 includes gain transistors 846, 847, 848, 849 and switches 846 and 841. The source of the transistor 847 is connected to the source of the transistor 848 at a node 844. The source of the transistor 846 is connected to the source of the transistor 849 at a node 851. The switch 846 has a first side connected to the source of the transistor 846 and the source of the transistor 849 at node 851 and another side of the switch 846 is connected to a node 853. The switch 841 has a first side connected to the source of the transistor 847 and the source of the transistor 848 at a node 844 and another side of the switch 841 is connected to the node 853. The positive LNA output, LNA_out_p, is provided over connection 843 and provided to the node 531, and the negative LNA output, LNA_out_n, is provided to a node 875 over connection 876 and provided to the node 521. In an exemplary embodiment, a VGA bias voltage may be applied to a center tap 532 of the second side 522 of the magnetic circuit 520. The bias voltage VGA bias may be generated by a bias circuit (not shown). Depending on the conductivity of the switches 846 and 841, the node 853 is connected to either node 844 or to node 851 based on the control signals Ctrl_ip and Ctrl_im. The switches 846 and 841 can be used to select the quadrant for determining phase shift. The off path helps neutralize the gate-drain capacitance (Cgd) of the on path.

In an exemplary embodiment, the Q VGA 855 includes gain transistors 856, 857, 858, 859 and switches 860 and 865. The source of the transistor 857 is connected to the source of the transistor 858 at a node 854. The source of the transistor 856 is connected to the source of the transistor 859 at a node 861. The switch 860 has a first side connected to the source of the transistor 856 and the source of the transistor 859 at the node 861 and another side of the switch 860 is connected to a node 863. The switch 865 has a first side connected to the source of the transistor 857 and the source of the transistor 858 at a node 854 and another side of the switch 865 is connected to the node 863. The positive LNA output, LNA_out_p, is provided over connection 862 and the negative LNA output, LNA_out_n, is provided from a node 875. Depending on the conductivity of the switches 860 and 865, the node 863 is connected to either node 861 or to node 854 based on the control signals Ctrl_Qp and Ctrl_Qm. The switches 860 and 865 can be used to select the quadrant for phase shift. The off path helps neutralize the gate-drain capacitance (Cgd) of the on path

A drain of the transistor 846 is connected to a drain of the transistor 848 and also connected to a connection 864. A drain of the transistor 847 is connected to a drain of the transistor 849 and also connected to a connection 866. The connection 864 is connected to one terminal of a first side 872 of a magnetic circuit 870, and the connection 866 is connected to another terminal of the first side 872 of the magnetic circuit 870. A second side 874 of the magnetic circuit 870 is connected to a QHG 890. The first side 872 of the magnetic circuit 870 and the second side 874 of the magnetic circuit 870 are magnetically coupled.

A drain of the transistor 856 is connected to a drain of the transistor 858 and also connected to a connection 867. A drain of the transistor 857 is connected to a drain of the transistor 859 and also connected to a connection 868. The connection 867 is connected to one terminal of a first side 882 of a magnetic circuit 880, and the connection 868 is connected to another terminal of the first side 882 of the magnetic circuit 880. A second side 884 of the magnetic circuit 880 is connected to the QHG 890. The first side 882 of the magnetic circuit 880 and the second side 884 of the magnetic circuit 880 are magnetically coupled.

An output of the HQG 890 is provided over connections 891 and 892.

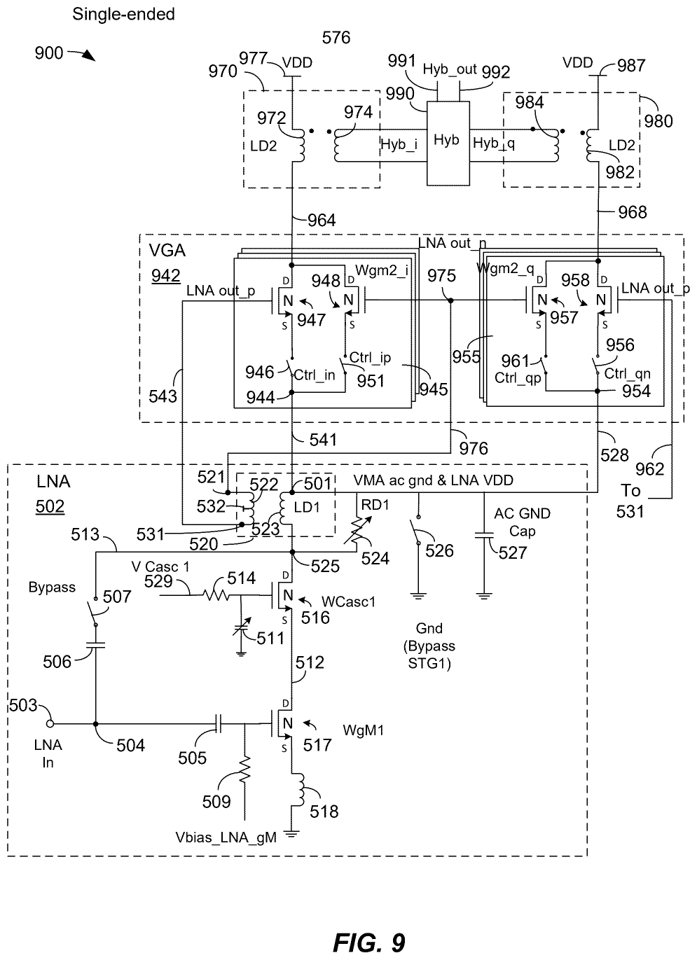

FIG. 9 is a diagram 900 showing a detailed view of the portion of the radio frequency (RF) front end of FIG. 5 in accordance with an exemplary embodiment. The diagram 900 shows the portion of the RF front end in a single-ended input VGA implementation. Elements in FIG. 9 that are identical to those in FIG. 5 will be identically numbered. In an exemplary embodiment, in a single-ended implementation, the VGA 942 includes an I VGA 945 and a Q VGA 955.

In an exemplary embodiment, the I VGA 945 includes transistors 947 and 948, switches 946 and 951 and a node 944. The LNA_out_p signal is provided to the transistor 947 over connection 543 and provided to the node 531, and the LNA_out_n signal is provided to the transistor 948 at node 975 over connection 976 and provided to the node 521. In an exemplary embodiment, a VGA bias voltage may be applied to a center tap 532 of the second side 522 of the magnetic circuit 520. The VGA bias voltage may be generated by a bias circuit (not shown).

In an exemplary embodiment, the Q VGA 955 includes transistors 957 and 958, switches 956 and 961 and a node 954. The LNA_out_p signal is provided to the transistor 958 from the node 531 over connection 962 and the LNA_out_n signal is provided to the transistor 957 at node 975 over connection 976 and provided to the node 521.

In this single-ended implementation, the output of the LNA 502 is differential; however, the VMA control signals Ctrl_ip/Ctrl_qp and Ctrl_in/Ctrl_qn select which LNA output to use (LNA_out_p or LNA_out_n) based on the desired quadrant.

In an exemplary embodiment, an output of the I VGA 945 is provided over connection 964, and an output of the Q VGA 955 is provided over connections 968. The signal on connections 964 is provided to a magnetic circuit 970 and the signal on connection 968 is provided to a magnetic circuit 980. The first side 972 of the magnetic circuit 970 and the second side 974 of the magnetic circuit 970 are magnetically coupled.

In an exemplary embodiment, the magnetic circuit 970 may be a transformer and may include a first side 972 and a second side 974. A voltage, VDD is provided to one terminal of the first side 972 at a connection 977. The output of the I VGA 945 may be provided to the other terminal of the first side 972 over connection 964. An output signal is provided from the second side 974 to the HQG 990.

In an exemplary embodiment, the magnetic circuit 980 may be a transformer and may include a first side 982 and a second side 984. The first side 982 of the magnetic circuit 980 and the second side 984 of the magnetic circuit 980 are magnetically coupled. A voltage, VDD is provided to one terminal of the first side 982 at a connection 587. The output of the Q VGA 955 may be provided to the other terminal of the first side 982 over connection 968. An output signal is provided from the second side 984 to the HQG 990. The output of the HQG 990 is provided over connections 991 and 992.

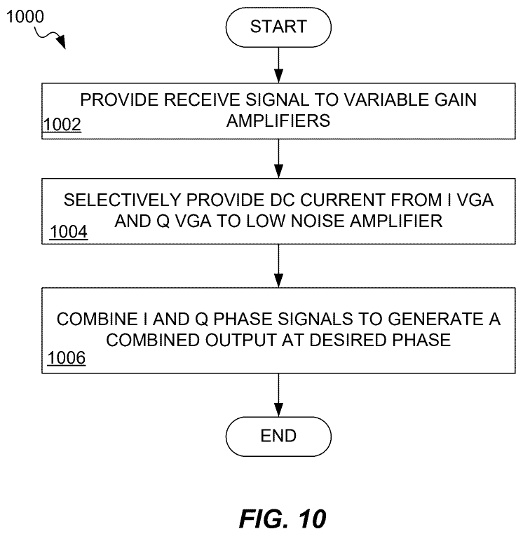

FIG. 10 is a flow chart 1000 describing an example of the operation of a method for providing current to a low noise amplifier. The blocks in the method 1000 can be performed in or out of the order shown, and in some embodiments, can be performed at least in part in parallel.

In block 1002, receive signals are provided to variable gain amplifiers. For example, RF signals are provided over connection 416 to the I VGA 434 and to the Q VGA 436. Similarly, RF signals are provided over connection 426 to the I VGA 444 and to the Q VGA 446.

In block 1004, current is selectively provided from the I VGA and the Q VGA to a low noise amplifier (LNA). For example, in a high-gain operating mode, the switches 507 and 526 are controlled such that DC current from the I VGA 545 and the Q VGA 555 is provided over connections 541 and 528 to the node 501 to supply additional DC current to the LNA 502.

In block 1006, the in phase and quadrature signals are combined to generate an output at a desired phase. For example, the HQG 590 combines the output of the I VGA 545 on connections 564 and 566 and the output of the Q VGA 555 on connections 567 and 568 and provides a combined output at a desired phase on connections 591 and 592.

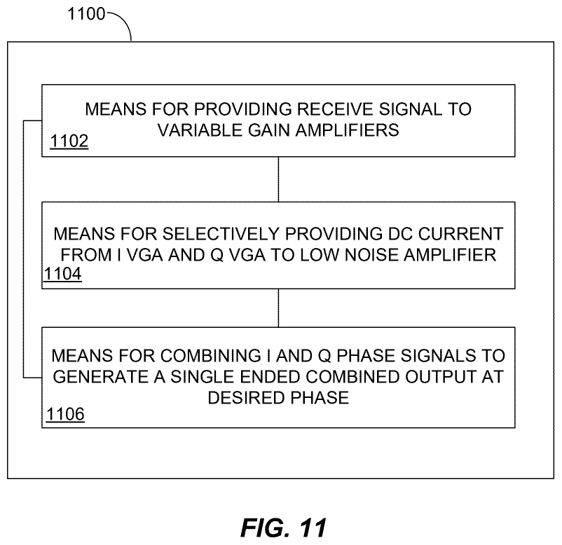

FIG. 11 is a functional block diagram of an apparatus 1100 for providing current to a low noise amplifier. The apparatus 1100 comprises means 1102 for providing receive signals to variable gain amplifiers. In certain embodiments, the means 1102 for providing receive signals to variable gain amplifiers can be configured to perform one or more of the functions described in operation block 1002 of method 1000 (FIG. 10). In an exemplary embodiment, the means 1002 for providing receive signals to variable gain amplifiers may comprise the LNA 414 providing RF signals over connection 416 to the I VGA 434 and to the Q VGA 436 and the LNA 424 providing RF signals over connection 426 to the I VGA 444 and to the Q VGA 446.

The apparatus 1100 may also comprise means 1104 for selectively providing DC current from the I VGA and the Q VGA to a low noise amplifier (LNA). In certain embodiments, the means 1104 for selectively providing DC current from the I VGA and the Q VGA to a low noise amplifier (LNA) can be configured to perform one or more of the functions described in operation block 1004 of method 1000 (FIG. 10). In an exemplary embodiment, the means 1004 for selectively providing DC current from the I VGA and the Q VGA to a low noise amplifier (LNA) may comprise in a high-gain operating mode, controlling the switches 507 and 526 so that DC current is provided from the I VGA 545 and the Q VGA 555 over connections 541 and 528 to the node 501 to supply additional DC current to the LNA 502.

The apparatus 1100 may also comprise means 1106 for combining the in phase and quadrature signals to generate an output at a desired phase. In certain embodiments, the means 1106 for combining in phase and quadrature signals to generate an output at a desired phase can be configured to perform one or more of the functions described in operation block 1006 of method 1000 (FIG. 10). In an exemplary embodiment, the means 1106 for combining in phase and quadrature signals to generate an output at a desired phase may comprise the HQG 590 combining the output of the I VGA 545 on connections 564 and 566 and the output of the Q VGA 555 on connections 567 and 568 provides a combined output at a desired phase on connections 591 and 592.

Implementation examples are described in the following numbered clauses:

1. A radio frequency (RF) front end for a communication system, comprising: a phase shifter having an in phase variable gain amplifier (I VGA) and a quadrature VGA (Q VGA) configured to receive radio frequency (RF) signals, the I VGA and the Q VGA configured to provide a selectable output to primary sides of first and second electromagnetic (EM) elements, respectively, the I VGA and the Q VGA configured to selectively provide DC current to a low noise amplifier (LNA).

2. The RF front end of clause 1, wherein in a first mode (high-gain), DC current from the I VGA and the Q VGA is provided to the LNA.

3. The RF front end of clause 1, wherein in a second mode (low-gain), the LNA is bypassed to provide the I VGA and the Q VGA with additional voltage headroom to improve linearity.

4. The RF front end of any of clauses 1 through 3, wherein the I VGA and the Q VGA each comprise a single gain transistor.

5. The RF front end of clause 4, wherein each single gain transistor comprises a drain connected to a pair of transistors configured as switches.

6. The RF front end of any of clauses 1 through 5, further comprising a hybrid quadrature generator (HQG) configured to receive and combine an output of the phase shifter.

7. The RF front end of any of clauses 1 through 6, wherein the I VGA and the Q VGA are configured for single-ended operation.

8. The RF front end of any of clauses 1 through 6, wherein the I VGA and the Q VGA are configured for differential operation.

9. A method for providing current to a low noise amplifier (LNA) in a radio frequency (RF) front end, comprising: providing radio frequency (RF) receive signals to an in phase variable gain amplifier (I VGA) and to a quadrature variable gain amplifier (Q VGA); selectively providing DC current from the I VGA and from the Q VGA to a low noise amplifier (LNA); and combining an output of the I VGA and the Q VGA to provide a combined output at a desired phase.

10. The method of clause 9, wherein in a first mode (high-gain), DC current is provided from the I VGA and the Q VGA to the LNA.

11. The method of clause 9, wherein in a second mode (low-gain), bypassing the LNA to provide the I VGA and the Q VGA with additional voltage headroom to improve linearity.

12. The method of any of clauses 9 through 11, further comprising implementing the I VGA and the Q VGA using a single gain transistor.

13. The method of clause 12, wherein each single gain transistor comprises a drain connected to a pair of transistors configured as switches.

14. The method of any of clauses 9 through 13, further comprising combining an output of the phase shifter in a hybrid quadrature generator (HQG).

15. The method of any of clauses 9 through 14, further comprising operating the I VGA and the Q VGA in a single-ended configuration.

16. The method of any of clauses 9 through 15, further comprising operating the I VGA and the Q VGA in a differential configuration.

17. A receive circuit, comprising: a low noise amplifier (LNA) circuit; an in phase variable gain amplifier (I VGA) and a quadrature VGA (Q VGA), each of the I VGA and the Q VGA having a gain transistor with a control terminal connected to an output of the LNA circuit, each gain transistor having a first terminal connected to a supply node of the LNA circuit and a second terminal connected to respective outputs of the I VGA and the Q VGA; and a hybrid quadrature generator (HQG) connected to the I VGA and the Q VGA.

18. The receive circuit of clause 17, wherein LNA circuit has a bypass path around gain elements of the LNA circuit.

19. The receive circuit of any of clauses 17 through 18, wherein the I VGA and the Q VGA further comprise cascode transistors connected to each gain transistor and the cascode transistors are biased as switches.

20. The receive circuit of any of clauses 17 through 19, wherein DC current from the I VGA and the Q VGA is provided to the LNA.

The circuit architecture described herein described herein may be implemented on one or more ICs, analog ICs, RFICs, mixed-signal ICs, ASICs, printed circuit boards (PCBs), electronic devices, etc. The circuit architecture described herein may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), heterojunction bipolar transistors (HBTs), high electron mobility transistors (HEMTs), silicon-on-insulator (SOI), etc.

An apparatus implementing the circuit described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

Although selected aspects have been illustrated and described in detail, it will be understood that various substitutions and alterations may be made therein without departing from the spirit and scope of the present invention, as defined by the following claims.

What is claimed is:

1. A radio frequency (RF) front end for a communication system, comprising:
a phase shifter having an in phase variable gain amplifier (I VGA) and a quadrature VGA (Q VGA) configured to receive radio frequency (RF) signals, the I VGA and the Q VGA configured to provide a selectable output to primary sides of first and second electromagnetic (EM) elements, respectively, the I VGA and the Q VGA configured to selectively provide DC current to a low noise amplifier (LNA).

2. The RF front end of claim 1, wherein in a first mode (high-gain), DC current from the I VGA and the Q VGA is provided to the LNA.

3. The RF front end of claim 1, wherein in a second mode (low-gain), the LNA is bypassed to provide the I VGA and the Q VGA with additional voltage headroom to improve linearity.

4. The RF front end of claim 1, wherein the I VGA and the Q VGA each comprise a single gain transistor.

5. The RF front end of claim 4, wherein each single gain transistor comprises a drain connected to a pair of transistors configured as switches.

6. The RF front end of claim 1, further comprising a hybrid quadrature generator (HQG) configured to receive and combine an output of the phase shifter.

7. The RF front end of claim 1, wherein the I VGA and the Q VGA are configured for single-ended operation.

8. The RF front end of claim 1, wherein the I VGA and the Q VGA are configured for differential operation.

9. A method for providing current to a low noise amplifier (LNA) in a radio frequency (RF) front end, comprising:
providing radio frequency (RF) receive signals to an in phase variable gain amplifier (I VGA) and to a quadrature variable gain amplifier (Q VGA);
selectively providing DC current from the I VGA and from the Q VGA to a low noise amplifier (LNA); and
combining an output of the I VGA and the Q VGA to provide a combined output at a desired phase.

10. The method of claim 9, wherein in a first mode (high-gain), DC current is provided from the I VGA and the Q VGA to the LNA.

11. The method of claim 9, wherein in a second mode (low-gain), bypassing the LNA to provide the I VGA and the Q VGA with additional voltage headroom to improve linearity.

12. The method of claim 9, further comprising implementing the I VGA and the Q VGA using a single gain transistor.

13. The method of claim 12, wherein each single gain transistor comprises a drain connected to a pair of transistors configured as switches.

14. The method of claim 9, further comprising combining an output of the I VGA and the Q VGA in a hybrid quadrature generator (HQG).

15. The method of claim 9, further comprising operating the I VGA and the Q VGA in a single-ended configuration.

16. The method of claim 9, further comprising operating the I VGA and the Q VGA in a differential configuration.

17. A receive circuit, comprising:
a low noise amplifier (LNA) circuit;
an in phase variable gain amplifier (I VGA) and a quadrature VGA (Q VGA), each of the I VGA and the Q VGA having a gain transistor with a control terminal connected to an output of the LNA circuit, each gain transistor having a first terminal connected to a supply node of the LNA circuit and a second terminal connected to respective outputs of the I VGA and the Q VGA; and
a hybrid quadrature generator (HQG) connected to the I VGA and the Q VGA.

18. The receive circuit of claim 17, wherein LNA circuit has a bypass path around gain elements of the LNA circuit.

19. The receive circuit of claim 17, wherein the I VGA and the Q VGA further comprise cascode transistors connected to each gain transistor and the cascode transistors are biased as switches.

20. The receive circuit of claim 1, wherein DC current from the I VGA and the Q VGA is provided to the LNA.
